(19) United States
(12) Patent Application Publication
(10) Pub. No.: US 2007/0007579 A1
(43) Pub. Date: Jan. 11, 2007

(54) Memory cell comprising a thin film three-terminal switching device having a metal source and /or drain region

(75) Inventors: Roy E. Scheuerlein, Cupertino, CA (US); Christopher J. Petti, Mountain View, CA (US)

Correspondence Address: MATRIX SEMICONDUCTOR, INC., 3230 SCOTT BOULEVARD, SANTA CLARA, CA, 95054, US

(73) Assignee: Matrix Semiconductor, Inc., Santa Clara, CA (US)

(21) Appl. No.: 11/179,095

(22) Filed: Jul. 11, 2005

(51) Int. Cl. H01L 29/76

(52) U.S. Cl. 257/315

(57) ABSTRACT

A nonvolatile memory cell comprising a switchable resistor memory element and a thin-film three-terminal switching device, preferably a MOSFET, in series. The switchable resistor memory element has the property of having at least two stable resistance states, for example a high-resistance state and a low-resistance state. It is switched between the two states, and its resistance state (and thus the data state of the cell) is sensed by providing appropriate current through the three-terminal switching device. Preferred embodiments of the present invention include a highly dense monolithic three dimensional memory array in which multiple memory levels of such memory cells are formed above a single substrate such as a monocrystalline silicon wafer.

### RELATED APPLICATIONS

This application is related to Scheuerlein, U.S. patent application Ser. No. ______, “Nonvolatile Memory Cell Comprising Switchable Resistor and Transistor” (attorney docket number MA-157), hereinafter the application; to Scheuerlein, U.S. patent application Ser. No. ______, “Apparatus and Method for Reading an Array of Nonvolatile Memory”, (attorney docket number 023-0040), hereinafter the application; and to Scheuerlein, U.S. patent application Ser. No. ______, “Apparatus and Method for Programming an Array of Nonvolatile Memory”, (attorney docket number 023-0041), hereinafter the ______ application, all assigned to the assignee of the present invention, filed on even date herewith and hereby incorporated by reference in their entirety.

### BACKGROUND OF THE INVENTION

The invention relates to a nonvolatile memory cell comprising a switchable resistor memory element and a three-terminal switching device arranged in series.

There are materials that are switchable between at least two stable resistivity states by application of current or voltage. This property would make these materials attractive for use in nonvolatile memory arrays, which retain their memory state even when power is removed from the device.

Applying the voltages required to switch between resistivity states in large memory arrays presents many difficulties, however. When an individual cell is to be switched, other memory cells accessed through the same conductors may be inadvertently switched. There is also the danger of inadvertently switching the resistivity state of a memory cell while sensing it. Many circuit and fabrication challenges must be surmounted to form a large memory array using such materials.

### SUMMARY OF THE PREFERRED EMBODIMENTS

The present invention is defined by the following claims, and nothing in this section should be taken as a limitation on those claims. In general, the invention is directed to a nonvolatile memory cell, suitable for use in a monolithic three dimensional memory array, which includes a three-terminal switchable device, such as a MOSFET, in series with a switchable resistor memory element. The memory cell is formed as a thin film device, for example formed of deposited material, rather than being formed in a monocrystalline wafer substrate.

A first aspect of the invention provides for a nonvolatile memory cell comprising a switchable resistor memory element; and a thin film three-terminal switching device comprising a channel layer, the thin film three-terminal switching device in series with the switchable resistor memory element, wherein the thin film three-terminal switching device does not include a doped semiconductor drain region, or the thin film three-terminal switching device does not include a doped semiconductor source region, or the thin film three-terminal switching device includes neither a doped semiconductor drain region nor a doped semiconductor source region.

A preferred embodiment of the invention provides for a monolithic three dimensional memory array formed above a substrate comprising: a) a first memory level, the first memory level comprising a first plurality of nonvolatile memory cells, each first memory cell comprising: i) a switchable resistor memory element; and ii) a three-terminal switching device comprising a channel layer and a gate electrode, wherein the three-terminal switching device lacks a doped semiconductor source region, a doped semiconductor drain region, or both, and b) a second memory level monolithically formed above the first memory level.

Another aspect of the invention provides for a nonvolatile memory cell comprising: a switchable resistor memory element; and a thin film transistor comprising a channel layer and a gate electrode wherein, when a threshold voltage is applied to the gate electrode, an inversion region forms in the channel layer, and current flows through the inversion region between a first region in contact with the channel layer and a second region in contact with the channel layer, wherein either the first region or the second region does not comprise semiconductor material.

Yet another aspect of the invention provides for a nonvolatile memory cell comprising: a switchable resistor memory element; and a three-terminal switching device having a channel layer, a source region, and a drain region, the three-terminal switching device and the switchable resistor memory element arranged in series, wherein, when the transistor is on, charge carriers travel from the source region through the channel layer to the drain region, wherein the nonvolatile memory cell comprises doped semiconductor material of only one conductivity type.

Still another aspect of the invention provides for a nonvolatile memory cell comprising: a switchable resistor memory element; and a thin film transistor comprising a channel layer, the thin film transistor and the switchable resistor memory element arranged in series, wherein a source contact between the source region and the channel layer or a drain contact between the drain region and the channel layer is a Schottky contact.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIGS. 1a and 1b are cross-sectional views describing structure and function of conventional MOSFET device.

FIGS. 2a-2h are cross-sectional views showing stages in formation of a preferred embodiment of the present invention.

FIGS. 3a-3j are cross-sectional views showing stages in formation of a another preferred embodiment of the present invention.

FIG. 4 is a cross-sectional view showing yet another preferred embodiment of the present invention.

FIG. 5a-5k are cross-sectional views showing stages in formation of another high-density embodiment of the present invention.

### DETAILED DESCRIPTION OF THE PREFERRED EMBODIMENTS

The related application filed on even date herewith (the ______ application, attorney docket number MA-157) pairs a three-terminal switching device, generally a MOSFET, with a switchable resistor memory element.

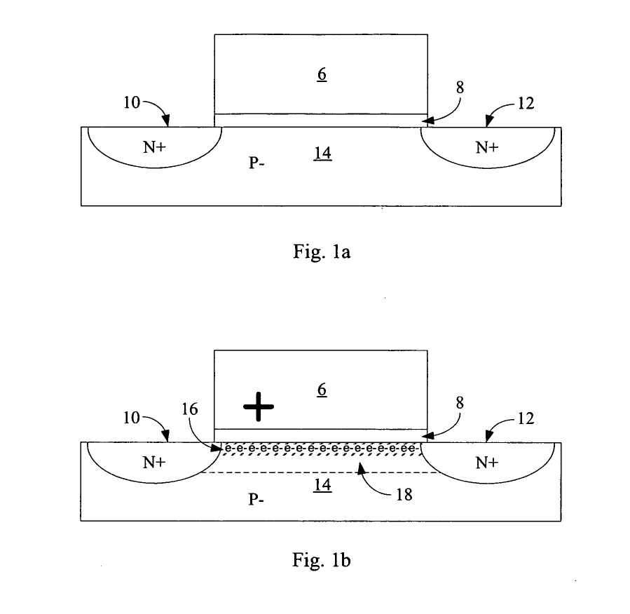

A conventional MOSFET is shown in FIG. 1a. It includes gate electrode 6, a gate dielectric 8, a source region 10, and a drain region 12. Source region 10 and drain region 12 are heavily doped semiconductor material of a first conductivity type. Between them is a channel layer 14 formed of lightly doped semiconductor material of the opposite conductivity type. For example, in a silicon NMOS device, the source region 10 and drain region 12 are heavily doped n-type silicon, while the channel region 14 is lightly doped p-type silicon. When no voltage is applied to gate electrode 6, the band gap between the lightly doped p-region 14 and the n-doped source and drain regions 10 and 12 serves as a barrier to current flow.

Turning to FIG. 1b, when sufficient positive voltage is applied to gate electrode 6, however, the potential at the top surface of the channel region 14 rises and electrons are attracted to the surface of the channel region 14, forming an inversion region 16. The barrier to conduction is lowered, and charge carriers can now travel between source region 10 and drain region 12 through the inversion region 16. A depletion region 18 is formed below the inversion region.

In some devices it becomes advantageous to form a three-terminal switching device such as a MOSFET in which the source and drain are not heavily doped semiconductor regions. For example, exposure to relatively high temperature is required to activate dopants in doped semiconductor source and drain regions. Certain materials (noble metals, for example) are best used with low processing temperatures; in some cases too low for effective dopant activation. Doped regions can also be formed by diffusing dopants from adjacent heavily doped regions. Avoiding this dopant diffusion step may be advantageous either to avoid the high temperatures required for sufficient diffusion or to avoid the necessity for formation of the adjacent donor region.

In embodiments of the present invention, a nonvolatile memory cell includes a switchable resistor memory element; and a thin film three-terminal switching device comprising a channel layer, the thin film three-terminal switching device in serier with the switchable resistor memory element, wherein the thin film three-terminal switching device does not include a doped semiconductor drain region, or the thin film three-terminal switching device does not include a doped semiconductor source region, or the thin film three-terminal switching device includes neither a doped semiconductor drain region nor a doped semiconductor source region. If this device is an enhancement-mode MOSFET, when the thin film three-terminal switching device is on, charge carriers travel through an inversion region formed in the channel layer between a first region in contact with the channel layer and a second region in contact with the channel layer.

In MOSFET embodiments, a metal, or a material that electrically behaves like a metal, replaces the doped semiconductor source region, drain region, or both. A Schottky barrier is formed between the channel region and the metal source region, and/or between the channel region and the metal drain region. In such a device, with no gate voltage applied, a barrier to conduction exists between the semiconductor channel region and the metal source region, and/or between the semiconductor channel region and the metal drain region. Materials with work functions less than the electron affinity of the semiconductor material have a Fermi level that is within the conduction band level of the semiconductor and so would have little or no barrier to conduction with n type semiconductor regions. But the Fermi level of such materials is far from the valence band of the semiconductor, hence such materials, when in contact with the p-doped semiconductor, have a barrier to conduction into the semiconductor. When a positive voltage is applied to the gate electrode, an inversion region forms at the top of the p type semiconductor channel, the barrier is lowered, and a current can flow between the metal source and drain regions.

For simplicity, this discussion has described the formation of Schottky contacts between semiconductor material and a metal. In reality, though, a Schottky contact can be formed between a semiconductor material and a material that is metal-like but is not an elemental metal, so long as, in the metal-like material, the Fermi level falls within the conduction band. Materials which are not technically metals but which have this characteristic, including some metal silicides, metal nitrides (TiN, for example), and other conductive compounds may be used instead.

Different switchable resistor memory elements can be paired with the three-terminal switching device in a memory cell according to embodiments of the present invention, including, for example, amorphous silicon doped with V, Co, Ni, Pd, Fe or Mn (these materials are described more fully in Rose et al., U.S. Pat. No. 5,541,869.) Another class of material is taught by Ignatiev et al. in U.S. Pat. No. 6,473,332: These are perovskite materials such as Pr_{1-X}Ca_{X}MnO₃, La_{1-X}Ca_{X}MnO₃ (LCMO), LaSrMnO₃ (LSMO), or GdBaCo_{X}O_{Y} (GBCO). Another option for the switchable resistor memory element is a carbon-polymer film comprising carbon black particulates or graphite, for example, mixed into a plastic polymer, as taught by Jacobson et al. in U.S. Pat. No. 6,072,716.

A preferred material is taught by Campbell et al. in U.S. patent application Ser. No. 09/943190, and by Campbell in U.S. patent application Ser. No. 09/941544. This material is doped chalcogenide glass of the formula A_{X}B_{Y}, where A includes at least one element from Group IIIA (B, Al, Ga, In, Ti), Group IVA (C, Si, Ge, Sn, Pb), Group VA (N, P, As, Sb, Bi), or Group VIIA (F, Cl, Br, I, At) of the periodic table, where B is selected from among S, Se and Te and mixtures thereof. The dopant is selected from among the noble metals and transition metals, including Ag, Au, Pt, Cu, Cd, Ir, Ru, Co, Cr, Mn or Ni. As will be described, in the present invention this chalcogenide glass (amorphous chalcogenide, not in a crystalline state) is formed in a memory cell adjacent to a reservoir of mobile metal ions. In some embodiments, another solid electrolyte material could substitute for chalcogenide glass. Operation of chalcogenide glass in a memory cell is described more fully in the ______ application filed on even date herewith; briefly, under voltage applied in one direction, mobile metal ions migrate from the adjacent ion reservoir, forming a conductive bridge through the chalcogenide layer. When the voltage is reversed, the metal ions migrate back into the ion reservoir, dissolving the conductive bridge and returning the chalcogenide material to its original high-resistivity state. The resistance of the conductive bridge can take many values dependent on the voltage or current applied to set the material into its low resistance state.

Yet another option is a class of binary metal oxides or nitrides, including NiO, Nb₂O₅, TiO₂, HfO₂, Al₂O₃, MgOₓ, CrO₂, VO, BN, and AlN, as described by Pagnia and Sotnick in “Bistable Switching in Electroformed Metal-Insulator-Metal Device,” Phys. Stat. Sol. (A) 108, 11-65 (1988). The resistance-switching behavior of these binary metal oxides and nitrides is not achieved through phase change. Memories making use of these materials are described in Herner et al., U.S. patent application Ser. No. 11/125,939, “Rewriteable Memory Cell Comprising a Diode and a Resistance-Switching Material,” filed May 9, 2005; and in Petti, U.S. application Ser. No. 11/143,269, “Rewriteable Memory Cell Comprising a Transistor and Resistance-Switching Material in Series,” filed Jun. 2, 2005, both owned by the assignee of the present invention and hereby incorporated by reference.

For simplicity, embodiments of the present invention will be described used with only one of these types of rewriteable switchable resistor memory elements, a chalcogenide glass adjacent to a mobile metal ion reservoir. It will be understood, however, that any of the other switchable materials can be used instead while the results fall within the scope o the invention. Also, for simplicity, the embodiments of the present invention will be described as storing two states in the memory cell. It will be understood, however that any of the embodiments can store more than two states in a memory cell by achieving more than two resistivity states.

Several preferred embodiments of the present invention are envisioned, including a channel trim embodiment, a silicide source/drain embodiment, a depletion mode switching device embodiment, and a reduced device area embodiment. Each of these embodiments will be described, and some preferred variations will be discussed for purposes of illustration, though it will be understood that many other embodiments are possible and fall within the scope of the invention.

Channel Trim Embodiment

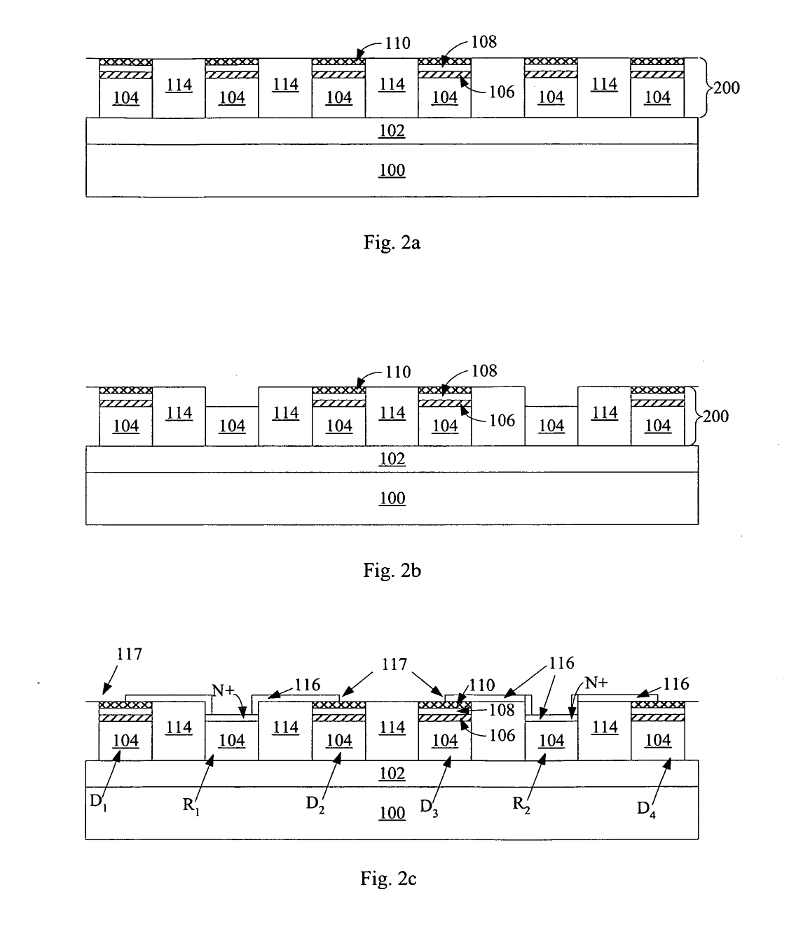

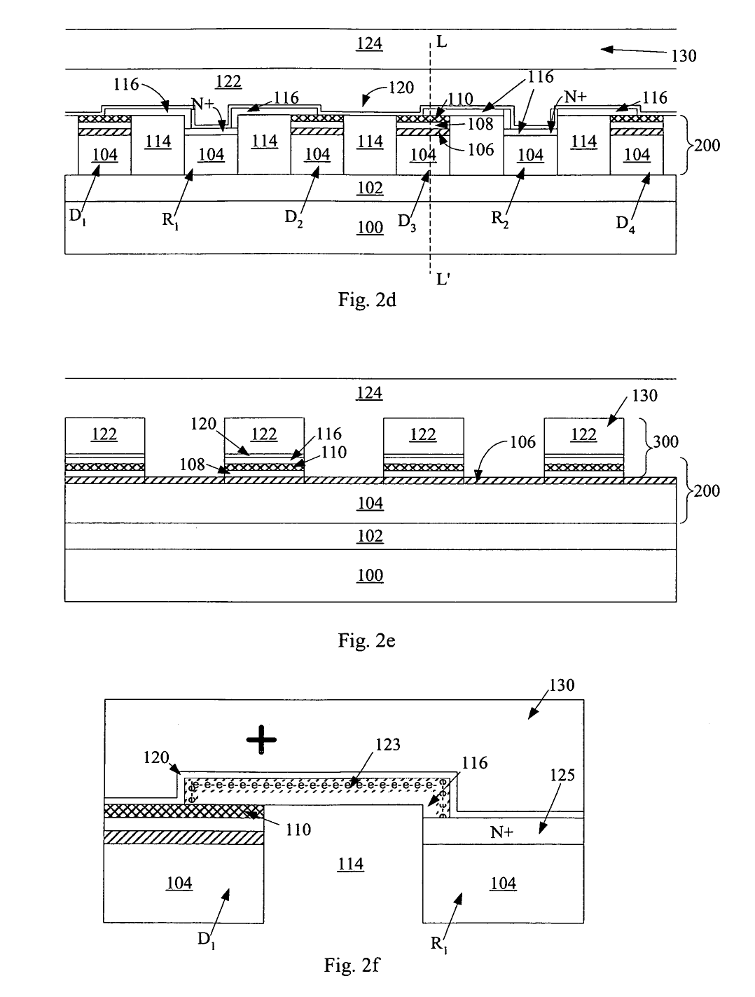

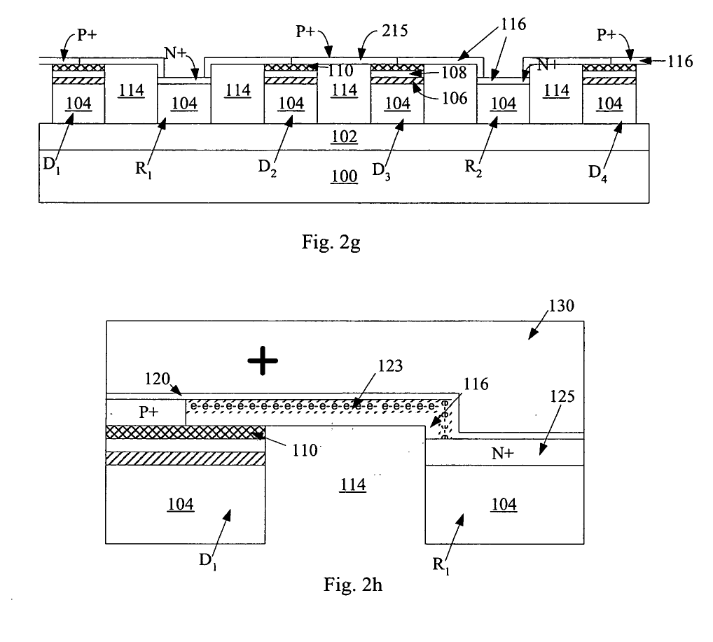

Turning to FIG. 2a, formation of the memory begins with a substrate 100. This substrate 100 can be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The substrate 100 may include integrated circuits fabricated therein. An insulating layer 102 is formed over substrate 100. Appropriate contacts (not shown) may be formed through the insulating layer 102.

Conductive material 104 is deposited on insulating layer 102. Conductive material 104 is preferably heavily doped n-type silicon. Conductive material 104 may be a conductive stack, but preferably conductive material 104 includes heavily doped n-type material. The top layer of conductive material 104 may includes a diffusion barrier (not shown). Conductive material 104 can be any appropriate thickness, for example between about 100 and about 250 nm thick.

Next the layers that will make up a switchable resistor memory element are formed. When the switchable resistor memory element comprises a solid electrolyte material adjacent to a mobile metal ion reservoir, in preferred embodiments the next layer deposited is a reservoir of mobile metal ions 106. This layer is between about 1 and about 100 nm thick, preferably between about 10 and about 30 nm thick. Ion reservoir 106 is any material that can provide suitable mobile metal ions, preferably silver ions.

An ion conductor layer 108 is deposited next. Layer 108 is a solid electrolyte material, preferably comprising chalcogenide glass, of the formula A_{X}B_{Y}, where A includes at least one element from Group IIIA (B, Al, Ga, In, Ti), Group IVA (C, Si, Ge, Sn, Pb), Group VA (N, P, As, Sb, Bi), or Group VIIA (F, Cl, Br, I, At) of the periodic table, where B is selected from among S, Se and Te and mixtures thereof. The dopant is selected from among the noble metals and transition metals, including Ag, Au, Pt, Cu, Cd, Ir, Ru, Co, Cr, Mn or Ni. Chalcogenide layer 108 is preferably formed in an amorphous state. Layer 108 is in contact with ion reservoir 106.

Note that some chalcogenide memories operate by undergoing phase change between an amorphous and a crystalline state. As described, the memory cells of embodiments of the present invention have a different mechanism, formation and dissolution of a conductive bridge, and should not undergo phase change. Thus chalcogenides that enter the crystalline phase less easily may be preferred. Chalcogenide layer 108 is preferably between about 10 and about 50 nm thick, preferably about 35 nm thick.

Top electrode 110, deposited next, is any appropriate electrode material. This should be a material that will not readily provide mobile metal ions to chalcogenide layer 108 under an electric field. Top electrode 110 can be, for example, tungsten, nickel, molybdenum, platinum, metal silicides, conductive nitrides such as titanium nitride, or heavily doped polysilicon. Top electrode 110 is preferably between about 10 and about 50 nm thick.

In a preferred embodiment, top electrode 110 will be formed of a low work function material, such as Al, Ti, Nb, Ag, Hf, Ta, Cu, Mn, W, TiN, some silicides, such as cobalt suicide or erbium suicide, and transistion metal silicon nitrides such as TaSiN, MoSiN, HfSiN, TiSiN preferably with 25% to 60% silicon, which will form a Schottky barrier in contact with the semiconductor channel material, preferably silicon, germanium, or a silicon-germanium alloy, yet to be deposited. Most preferred materials for top electrode 110 include Ti, Ta, TaSiN, TiN, TiSiN, ErSi_{1.7}, or W.

Other appropriate barrier layers, adhesion layers, or etch stop layers may be included in addition to the layers described.

Next conductive material 104, ion reservoir 106, chalcogenide layer 108, and top electrode 110 are patterned and etched into a plurality of substantially parallel, substantially coplanar lines 200.

Dielectric fill 114, for example HDP oxide, is deposited over and between lines 200, filling gaps between them. The overfill of dielectric fill 114 is removed to expose top electrode layer 110 at the tops of lines 200, and a planarizing step, for example by chemical-mechanical planarization (CMP) or etchback, coexposes top electrode layer 110 and dielectric fill 114 at a substantially planar surface. The structure at this point is shown in FIG. 2a.

Next, turning to FIG. 2b, a masking step is performed to expose every third line among lines 200, and top electrode 110, chalcogenide layer 108, ion reservoir 106 are etched and removed from the exposed lines only. If a diffusion barrier was included between conductive material 204, the diffusion barrier should be removed by this etch as well. The exposed lines will be reference lines in the completed array. As shown, layers 110, 108, and 106 remain on the other two of three lines, which will become data lines in the completed array.

Ion reservoir 106, chalcogenide layer 108, and electrode layer 110 form a switchable resistor memory element.

Turning to FIG. 2c, next a channel layer 116 is deposited. (In this discussion, the term “channel layer” means a semiconductor layer in a three-terminal device through which current will flow between source and drain when an “on” voltage is applied to the gate. In a MOSFET, current flows through an inversion region that forms in the channel layer, though, in an embodiment to be described later, the channel layer is conductive when not depleted, and no inversion region is required to form for the channel layer to be conductive.) This layer is a semiconductor material, preferably lightly doped with a p-type dopant, and is preferably between about 10 and about 50 nm thick. In preferred embodiments, channel layer 116 is between about 10 and about 20 nm thick. Channel layer 116 is a deposited semiconductor material, and can be silicon, germanium, or an alloy of silicon and germanium. In preferred embodiments, channel layer 116 is amorphous as deposited, and will be crystallized in a following anneal step or during subsequent thermal processing, and after recrystallization will be polycrystalline. Methods to maximize grain size in deposited semiconductor channel layers are described in Gu, U.S. Pat. No. 6,713,371, “Large Grain Size Polysilicon Films Formed by Nuclei-Induced Solid Phase Crystallization”; and in Gu et al., U.S. patent application Ser. No. 10/681,509, “Uniform Seeding to Control Grain and Defect Density of Crystallized Silicon for Use in Sub-Micron Thin Film Transistors,” both owned by the assignee of the present invention and hereby incorporated by reference.

Note that during subsequent thermal steps, n-type dopant atoms will diffuse up from N+material 104 to form N+regions in channel layer 116, which will behave as either a source or drain region in the completed device. In the completed device each transistor will have one doped semiconductor source/drain region, and one non-semiconductor source/drain region.

Channel layer 116 is conformal, following the topography over which it is deposited. At the top of reference lines R₁ and R₂ where layers 110, 108, and 106 were removed, then, channel layer 116 has a corrugated shape. This corrugated shape increases effective channel length, which may improve device performance at very small dimensions.

In the completed array, transistors will be formed between adjacent data lines and reference lines, but there should be no device formed between adjacent data lines, for example between data line D₂ and data line D₃. Channel layer 116 is selectively removed in region 117 between data lines D₂ and D₃ using conventional pattern and etch techniques.

Turning to FIG. 2d, a gate dielectric 120 is formed next. If channel layer 116 is silicon or a silicon-rich alloy, gate dielectric 120 may be a layer of silicon dioxide grown by an oxidation process such as thermal or plasma oxidation. In other embodiments, this layer is a deposited dielectric, for example silicon dioxide or higher-K dielectric materials such as Si₃N₄, Al₂O₃, HfO₂, HfSiON, or Ta₂O₅. Gate dielectric layer 120 is preferably between about 2 and about 10 nm. Higher-K dielectric gate dielectrics may be thicker than a gate dielectric formed of silicon dioxide.

Next select line material 122 is deposited. Select line material 122 can be any conductive material, including tungsten, aluminum, or heavily doped semiconductor material, for example polysilicon. In some embodiments, select line material 122 includes a first layer of n-type polysilicon, a thin layer of titanium, a thin layer of titanium nitride, and a second layer of n-type polysilicon. The titanium and titanium nitride will react with the surrounding polysilicon to form a titanium silicide layer, providing lower resistance.

Finally a pattern and etch step is performed to form select lines 300. This etch continues through gate dielectric layer 120, channel layer 116, and through top electrode 110. In preferred embodiments, etching continues through chalcogenide layer 108 as well. Select lines 300 must be fully isolated; chalcogenide layer 108 is typically high-resistance, but in a very large array even the low-conductance paths afforded by remaining chalcogenide material between adjacent select lines may be disadvantageous. Ion reservoir 106 is optionally etched as well. FIG. 2e shows the structure at ninety degrees along line L-L′ to the view shown in FIG. 2d after the select line etch is completed.

A dielectric material 124 is deposited over and between word lines 300, filling gaps between them. A planarizing step, for example by CMP, forms a substantially planar surface on an interlevel dielectric formed of dielectric material 124. A first memory level has been formed. Additional memory levels can be formed above this level.

Turning to FIG. 2f, when a positive voltage is applied to select line 130, an inversion region 123 forms in channel layer 116 adjacent to gate dielectric 120. Inversion region 123 is U-shaped, reaching from N+ source region 125 to top electrode 110, which behaves as a drain region. In the embodiment just described, source region 125 is formed of doped semiconductor material, while drain region 110 is not formed of doped semiconductor material. Depending on the voltages applied, top electrode 110 may serve as the source region while N+ region 125 serves as the drain region.

In a related embodiment, pictured in FIG. 2g, fabrication is the same except that the channel trim step of the prior embodiment is replaced with a doping step. It will be recalled that, as shown in FIG. 2c, channel layer 116 was selectively removed between adjacent data lines, for example between D₂ and D₃, to avoid formation of a parasitic device between them. Formation of this parasitic device can also be avoided by performing a masked ion implantation step so that region 215 between adjacent data lines such as D₂ and D₃ is doped with a P-type dopant.

Turning to FIG. 2h, in the embodiment of FIG. 2g, when a gate voltage is applied, an inversion region forms at the top of channel layer 116. The remaining thickness of channel layer 116, however, will serve as a barrier to flow of charge carriers between the inversion region and metal source/drain region 110. This difficulty is overcome by minimizing the thickness of channel layer 116 (to a thickness, for example, of 10-20 nm or less), and by increasing gate voltage to increase the size of the inversion region and to fully deplete the remaining thickness of channel layer 116, minimizing the barrier to conduction. Germanium and germanium alloys have higher carrier mobility than silicon, and are preferred for use in channel layer 116 in the embodiment of FIG. 2g.

In both of the embodiments just described, the device is NMOS; i.e., when the device is on, the majority carriers in the inversion region are electrons. If a silicide is used in a source/drain region in place of the conventional doped semiconductor material, a preferred silicide for this embodiment is ErSi_{1.7}. As will be apparent to those skilled in the art, the embodiments just described may instead be formed as PMOS; i.e. when the device is on, the majority carriers in the inversion region are holes. The preferred silicide in a PMOS embodiment is a silicide of platinum, PtSi. Cobalt silicide (CoSi₂) may be used in either PMOS or NMOS.

To summarize, for NMOS, appropriate non-semiconductor materials to replace the conventional N+ source/drain region are low work function materials such as Ti, Ta, TaSiN, TiN, TiSiN, ErSi_{1.7}, Nb, Ag, Hf, Mn, or W. For PMOS, appropriate materials to replace the conventional P+ source/drain region are high work function materials such as Au, Ni, or Pt, PtSi, MoSi₂, or WSi₂.

Silicide Source/Drain Embodiment

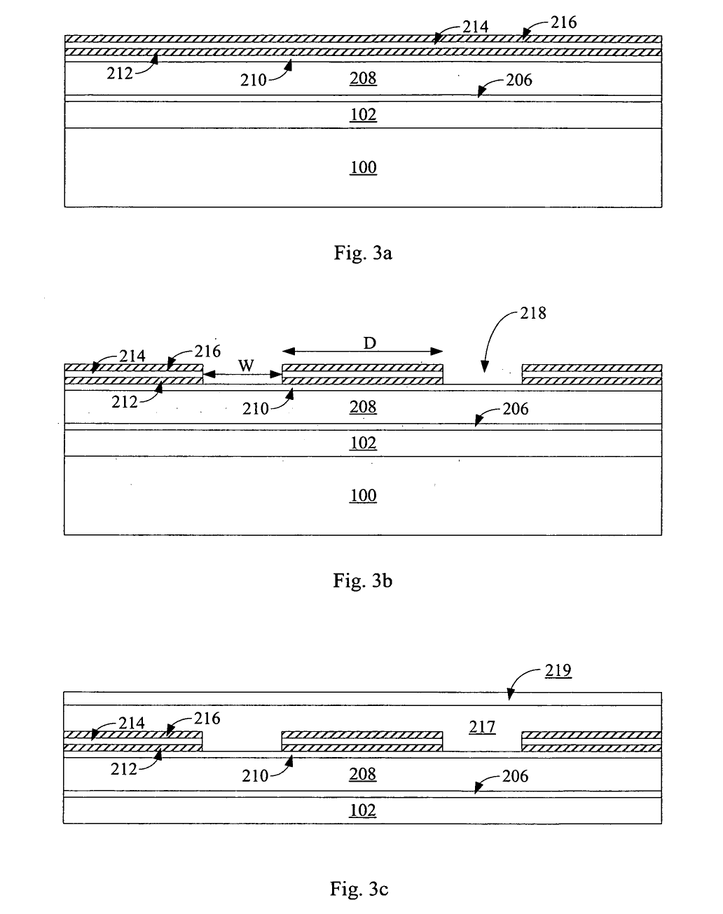

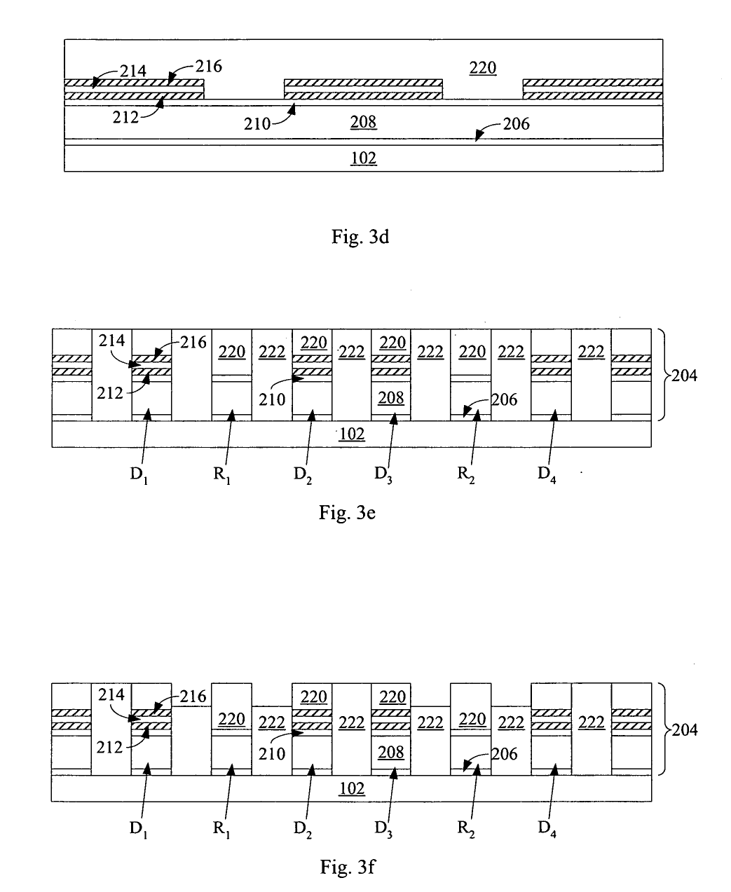

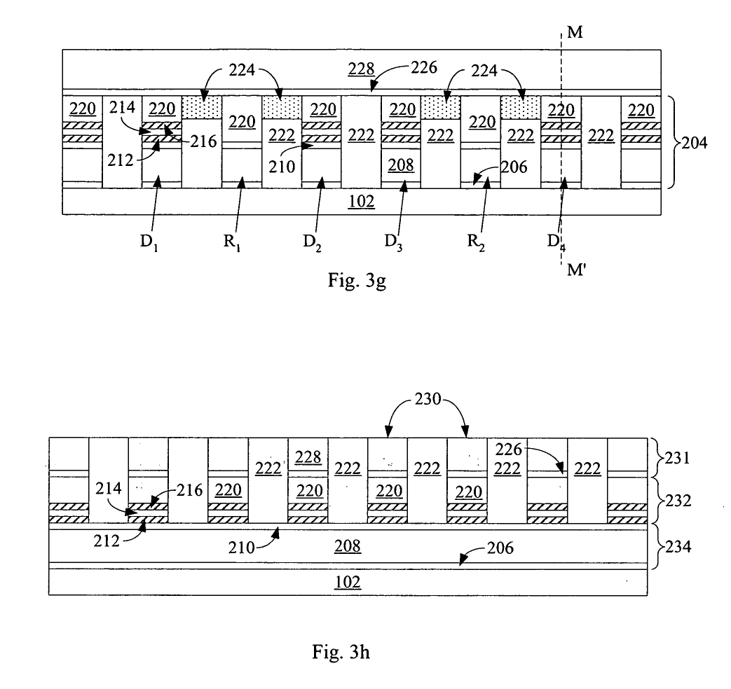

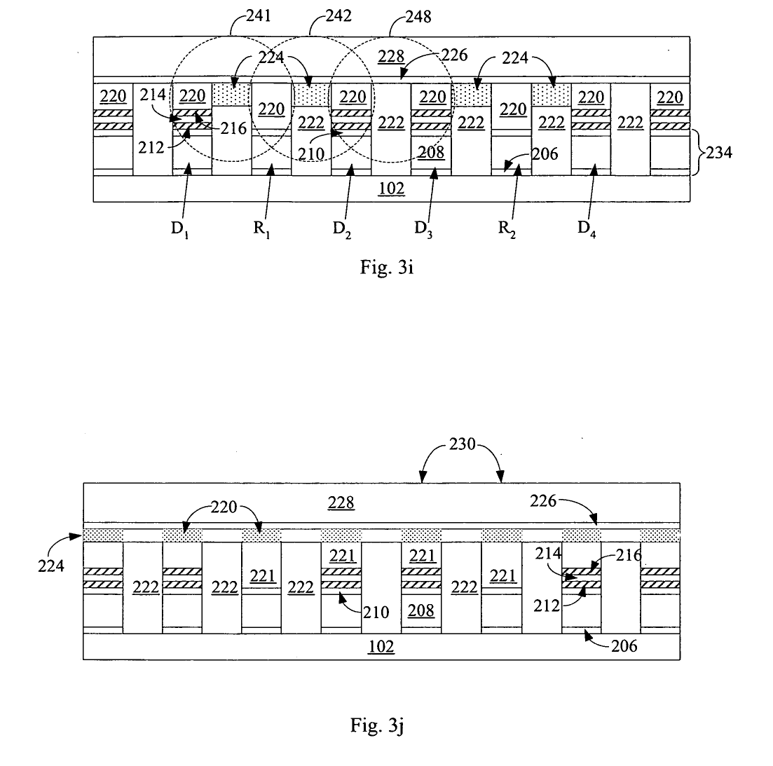

Turning to FIG. 3a, as in the prior embodiment, fabrication begins over a suitable substrate 100 and insulating layer 102. As described earlier, substrate 100 may include integrated circuits fabricated therein and appropriate contact structures.

Optionally an adhesion layer 206 of, for example, titanium nitride is deposited on insulating layer 102. Conductive layer 208, which may be formed of tungsten, aluminum or an aluminum alloy, heavily doped semiconductor material, or some other suitable material, is deposited next. Layer 208 can be any appropriate thickness, for example about 150 nm. Barrier layer 210 is deposited next; this layer is preferably between about 10 and about 40 nm, most preferably about 20 nm or less.

Next the layers making up a switchable resistor memory element are deposited. In this example these layers are ion reservoir 212 is deposited, chalcogenide layer 214, and top electrode layer 216. These layers may be as described in the previous embodiment. Any of the other switchable resistor memory elements described earlier (doped amorphous silicon, perovskites, etc.) may be used in any embodiment, but for simplicity only chalcogenide glass with an mobile metal ion reservoir will be described.

Turning to FIG. 3b, a pattern and etch step is performed to etch slots 218 through top electrode 216, chalcogenide layer 214, and, optionally, through ion reservoir 212. The width W of slots 218 is narrower than the distance D between them, preferably half distance D. For example, width W can be between about 90 and 200 nm, preferably about 180 nm, while distance D is between about 180 nm and about 400 nm, preferably about 360 nm. As will be described, reference lines will be formed at the location of the slots, and data lines and resistor memory elements will be formed between the slots.

Turning to FIG. 3c, in preferred embodiments silicon layer 217 is deposited. Silicon layer 217 is preferably about 120 nm thick. (In this and subsequent figures, substrate 100 has been omitted. Its presence will be assumed.) A layer 219 of erbium is deposited on silicon layer 217. Layer 219 is preferably about 60 nm thick. An anneal step, for example at about 400 degrees C., is performed to react silicon layer 217 and erbium layer 219, forming a silicide, ErSi_{1.7}. At the completion of the silicide reaction forming ErSi_{1.7} layer 220 (shown in FIG. 3d), all of silicon layer 217 should have been consumed. ErSi_{1.7} layer 220 is preferably about 120 nm thick.

In alternative embodiments (not shown), top electrode layer 216 could be omitted, and ErSi_{1.7} layer 220 could serve as the top electrode. In this case, ErSi_{1.7} layer 220 should be formed after the pattern and etch step of FIG. 3b, so that chalcogenide layer 214 and (optionally) ion reservoir 212 are removed in slots 218.

Turning to FIG. 3e, a pattern and etch step is performed to etch the layers formed so far into substantially parallel lines 204, which extend out of the page. The pitch of lines 204 should be about the same as the width W of the slots 218 formed in the etch step illustrated in FIG. 3b, for example between about 45 and about 100 nm, preferably about 90 nm. Ideally every third line 204 is centered in one of slots 218, though misalignment can be tolerated. Lines centered in the slots are referred to as reference lines designated R₁ and R₂. In this way, reference lines such as R₁ and R₂ do not include any portion of top electrode 216 or chalcogenide layer 214 (or of ion reservoir 212, if it was etched in the etch step that formed slots 218.) Lines formed between the slots will comprise data lines (D₁, D₂, D₃, and D₄) and switchable resistor memory elements comprising top electrod 216, chalcogenide layer 214 and ion reservoir 212.

Next a dielectric material 222 is deposited over and between lines 204, filling gaps between them. A planarizing step is performed, for example by CMP or etchback, to form a substantially planar surface coexposing tops of lines 204 separated by dielectric material 222. If this planarization is performed by CMP, about 30 nm or less of ErSi_{1.7} layer 220 may be removed.

Top electrode layer 216 and chalcogenide layer 214 remain in data lines, for example D₁, D₂ and D₃, but have been removed from reference lines R₁ and R₂. Next photoresist (not shown) is deposited and patterned such that the dielectric 222 between adjacent data lines, for example between D₂ and D₃, is protected during a dielectric etch step. For example, if dielectric 222 is HDP oxide, this is a timed oxide etch which removes between about 50 and about 70 nm of oxide. This etch should not expose chalcogenide layer 108 or ion reservoir 106. Oxide is thus recessed between adjacent data lines and reference lines (D₁ and R₁, R₁ and D₂, D₃ and R₂) but not between adjacent data lines (D₂ and D₃.) The photoresist is removed. The resulting structure is shown in FIG. 3f.

Turning to FIG. 3g, a channel layer 224 of a lightly doped or intrinsic semiconductor material, preferably lightly doped p-type silicon, germanium, or a silicon-germanium alloy, is deposited. This layer should be of sufficient thickness to completely fill, and preferably slightly overfill, the recesses created in the previous dielectric etch step. Channel layer 224 layer may be amorphous as deposited, but in preferred embodiments will be polycrystalline in the completed device. Next a planarization step, for example by CMP or etchback, is performed to remove overfill of channel layer 224, coexposing the semiconductor material of channel layer 224, ErSi_{1.7} layer 220, and dielectric 222.

A thin gate dielectric 226 is formed next, preferably by depositing between about 5 and 10 nm of, for example, silicon dioxide. Next a layer of conductive material 228 is deposited. This layer can be, for example, heavily doped n-type silicon, germanium, or a silicon-germanium alloy, or some other suitable conductive material, such as a metal or conductive metal compound, for example tantalum nitride. Layer 228 may be about 100 nm thick.

Next a pattern and etch step is performed, etching conductive layer 228, gate dielectric layer 226, and channel layer 224, and ErSi_{1.7} layer 220. This etch forms substantially parallel lines, preferably substantially perpendicular to the data lines and reference lines (D₁, D₂, R₁, etc.) formed earlier. The etch continues through top electrode 216, chalcogenide layer 214, and, optionally, ion reservoir 212, forming pillars 232. FIG. 3h shows the structure of FIG. 3g viewed at 90 degrees along line M-M′.

This etch has also made pillars 232 distinct from first rails 234. In this example, first rails 234 include adhesion layer 206, conductive layer 208, and barrier layer 210. Turning to FIG. 3i, first rails 234 include line sets, each line set consisting of two data lines (D₁ and D₂, for example, or D₃ and D₄) and one reference line (R₁ or R₂), the reference line immediately adjacent to and between the two data lines.

Turning to FIG. 3i, field effect transistors, for example 241 and 242, have been formed. Each is in electrical contact with a data line and a reference line; for example transistor 241 contacts data line D₁ and reference line R₁, while transistor 242 contacts data line D₂ and reference line R₁. Each transistor is arranged in series with a switchable resistor memory element (ion reservoir 212, chalcogenide layer 214, and top electrode 216) in one pillar 232, but not the other.

When transistor 241 is programmed, erased, and read, data line D₁ acts as a source or drain line to the field effect transistor 241, the immediately adjacent reference line R₁ acts as a drain or source line to the field effect transistor, and the select line 230 acts as a gate electrode.

Note that the channel layer 224 only exists between adjacent data lines and reference lines, as in transistors 241 and 242. At location 248, between adjacent data lines, no channel layer 224 exists, and no unwanted parasitic device is formed. In less preferred embodiments, the masking and dielectric etch step that assured that no parasitic device is formed may be omitted.

Dielectric fill 222 is deposited between top rails 231, and an interlevel dielectric is formed. A first memory level, pictured in FIG. 3h and 3i, has been formed. Additional memory levels can be stacked above this first memory level, fabrication beginning on the interlevel dielectric and proceeding as described, to form a monolithic three dimensional memory array.

A related embodiment is shown in FIG. 3j. Fabrication of this embodiment begins as in the embodiment just described, with deposition of conductive layer 208, barrier layer 210, ion reservoir 212, and chalcogenide layer 214, and top electrode 216. The etch of FIG. 3b, forming slots 218, etches top electrode 216, chalcogenide layer 214, and optionally ion reservoir 212. Erbium layer 221 is deposited next. A pattern and etch step forms parallel rails, including data D₁, reference line R₁, data line D₂, data line D₃, reference line R₂, etc. As in the prior embodiment, data lines include a switchable resistor memory element (in this example including ion reservoir 212, chalcogenide layer 214, and top electrode 216) while reference lines do not. Dielectric fill 222 is deposited over and between the data lines and reference lines, and a planarizing step coexposes erbium layer 221 at the tops of the data lines and reference lines and intervening dielectric fill 222. A channel layer 224, preferably of lightly doped p-type silicon, is deposited on erbium layer 221 and dielectric fill 222. This channel layer may be relatively thin, for example as thin as 10-20 nm. An anneal step causes a silicide reaction, forming ErSi_{1.7} regions 220 to form. In preferred embodiments, the silicide reaction consumes silicon throughout the entire thickness of channel layer 224. Preferably no unreacted erbium remains after the silicide reaction, either.

The memory level of FIG. 3j is completed by formation of gate dielectric 226 and select line material 228, followed by a pattern and etch step, etching through select line material 228, gate dielectric 226, channel layer 224 and ErSi_{1.7} regions 220, erbium layer 221, top electrode 216, chalcogenide layer 214, and optionally ion reservoir 212, forming select lines 230.

In the embodiment of FIG. 3j, it is preferred for the silicide reaction to consume the entire thickness of channel layer 224 above erbium layer 221, such that ErSi_{1.7} regions 220, which will serve as source and drain regions, extend the thickness of channel layer 224. In this case when a voltage is applied to select line 230, forming an inversion region at the top of channel layer 224, ErSi_{1.7} regions 220 will be in contact with the inversion region, minimizing any barrier to charge carriers between the inversion region and the source or drain regions 220. In less preferred embodiments, however, ErSi_{1.7} regions 220 may not occupy the entire thickness of channel layer 220, and some thin gap may exist between an inversion region and source and drain ErSi_{1.7} regions 220. The resulting conduction barrier may be overcome by increasing gate voltage, and such embodiments fall within the scope of the invention. As an optional embodiment an extra implantation step is included to dope the channel region between data lines to ensure these parasitic channel regions do not turn on.

To summarize, a nonvolatile memory cell in the array just describe comprises a switchable resistor memory element; and a thin film transistor comprising a channel layer, the thin film transistor and the switchable resistor memory element arranged in series, wherein, when the transistor is on, electrons flow between a source region in contact with the channel layer and a drain region in contact with the channel layer through an inversion region formed in the channel layer, wherein a source contact between the source region and the channel layer or a drain contact between the drain region and the channel layer is a Schottky barrier.

As in all embodiments, additional memory levels may be formed above the one just completed, forming a monolithic three dimensional memory array.

Depletion Mode Switching Device

In an alternative embodiment, the device formed in series with the switchable resistor memory element is a three-terminal switching device in which current is switched on and off by varying gate voltage. It is not a conventional MOSFET, however, in which current is conducted through the channel layer only when gate voltage is applied to form an inversion region.

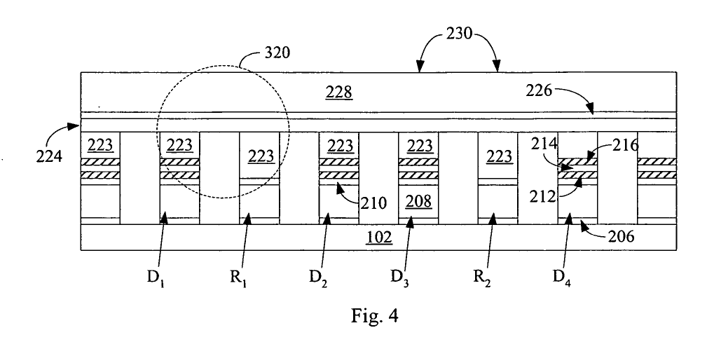

FIG. 4 shows an alternative embodiment. Construction of this embodiment begins as in the embodiment of FIGS. 3a through 3i: Conductive layer 208, barrier layer 210, ion reservoir 212, chalcogenide layer 214, and top electrode layer 216 are deposited, and an etch analogous to the etch of FIG. 3b etches through top electrode 216, chalcogenide layer 214, and optionally ion reservoir 212, forming slots (slots 218 of FIG. 2b). The next layer 223 is a material that will form a substantially ohmic contact with n-doped silicon or germanium. Preferred materials include AlNb, Ag, Hf, Ta, Cu, Mn, W, TiN, some silicides, such as cobalt silicide or erbium silicide, and transistion metal silicon nitrides such as TaSiN, MoSiN, HfSiN, TiSiN preferably with 25% to 60% silicon, though other materials having similar work functions may also be used. In some embodiments, ohmic layer 223 may serve as top electrode layer 216. The electron affinities of germanium and silicon are similar, and thus most materials appropriate for use with n-doped silicon can also be used with n-doped germanium or an n-doped silicon-germanium alloy.

A pattern and etch step forms substantially parallel conductive rails 204. As in prior embodiments, data lines D₁, D₂, and D₃ include a switchable resistor memory element, while reference lines R₁ and R₂ do not. Dielectric material 222 is deposited over and between rails 204, then a planarization step coexposes ohmic layer 223 and intervening dielectric fill 222.

Next a channel layer 224 is deposited. Unlike the channel layer 224 of a conventional MOSFET or of prior embodiments, this channel layer 224 is moderately to heavily doped n-type semiconductor material (silicon, germanium, or a silicon-germanium alloy), for example having a doping concentration of about 10¹⁷ to 10¹⁸ dopant atoms/cm³. Portions of the channel layer, e.g. between adjacent data lines D₂ and D₃, are doped with a p-type dopantin an optional processing step to ensure low leakage between data lines.

As in prior embodiments, the device is completed by forming gate dielectric layer 226 and select line material 228, then performing a pattern and etch step to form select lines 230 preferably substantially perpendicular to the data lines and reference lines formed earlier. Also as in prior embodiments, this etch step etches through select line material 228, gate dielectric 226, channel layer 224, ohmic layer 223, top electrode 216, chalcogendide layer 214, and optionally ion reservoir 212.

As shown in FIG. 4, a three-terminal switching device is formed at 320 between data line D₁ and reference line R₁. With a small negative voltage, for example −0.5 volts, applied to select line 230, all electrons are repelled from channel layer 224, leaving it fully depleted and non-conductive. Switching device 320 is in the “off” state. When a positive voltage, for example 1 volt, is applied to select line 230, electrons return to channel layer 224, which is now conductive, and switching device 320 is in the “on” state, though note that no inversion region has been formed in channel layer 224. By selecting appropriate voltages on data line D₁ and reference line R₁, the switchable resistor memory element including chalcogenide layer 214 can be switched between its low-resistance and high-resistance states.

At higher gate voltages, the transconductance (change in drain current per unit change in gate voltage) of this depletion mode device is generally lower than that of a conventional enhancement-mode MOSFET; thus this embodiment is most preferably used with switchable resistor memory elements that do not require large currents or voltages. For example, some binary metal oxides or nitrides require two or three volts and hundreds to thousands of microamps to switch, and may be a less advantageous choice for this embodiment, though such combination still falls within the scope of the present invention.

When this thin film switching device is on, charge carriers travel through the channel layer between a first region in contact with the channel layer and a second region in contact with the channel layer, wherein both the first region and the second region consist essentially of a material that forms a substantially ohmic contact with the channel layer. If the charge carriers are electrons, the electrons flow between a source region in contact with the channel layer and a drain region in contact with the channel layer through a majority carrier region in the channel layer.

As in the prior embodiments, the structure shown in FIG. 4 is a first memory level. After formation of a planarized interlevel dielectric, additional memory levels can be formed above this memory level to form a monolithic three dimensional memory array.

Reduced Device Area

Another embodiment provides for a device occupying a smaller area, allowing for a denser memory array. This embodiment can be formed as either a depletion mode device or as an enhancement-mode MOSFET.

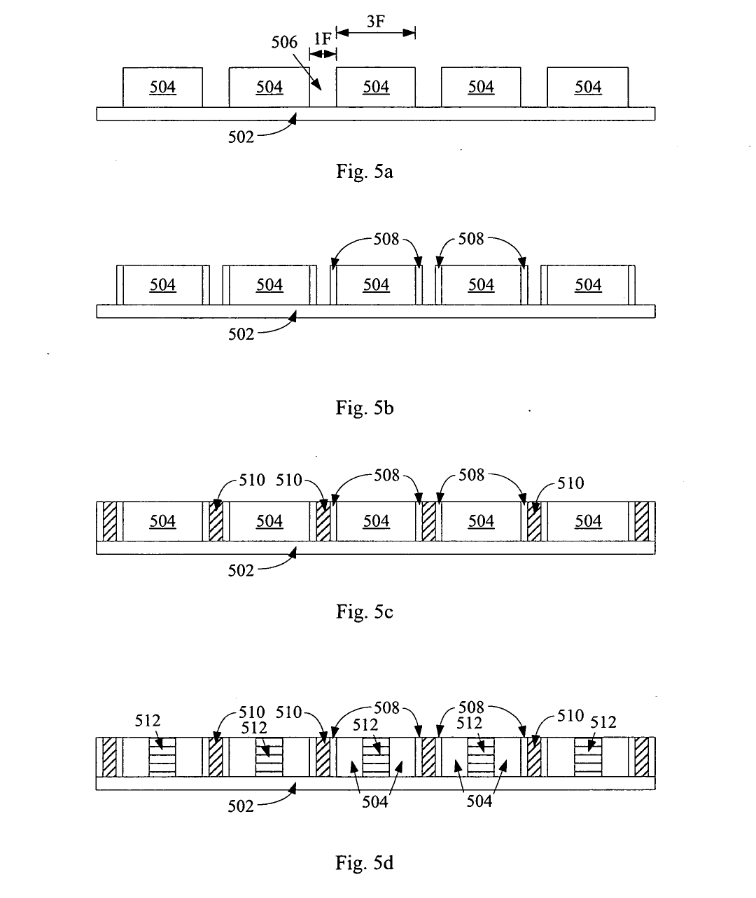

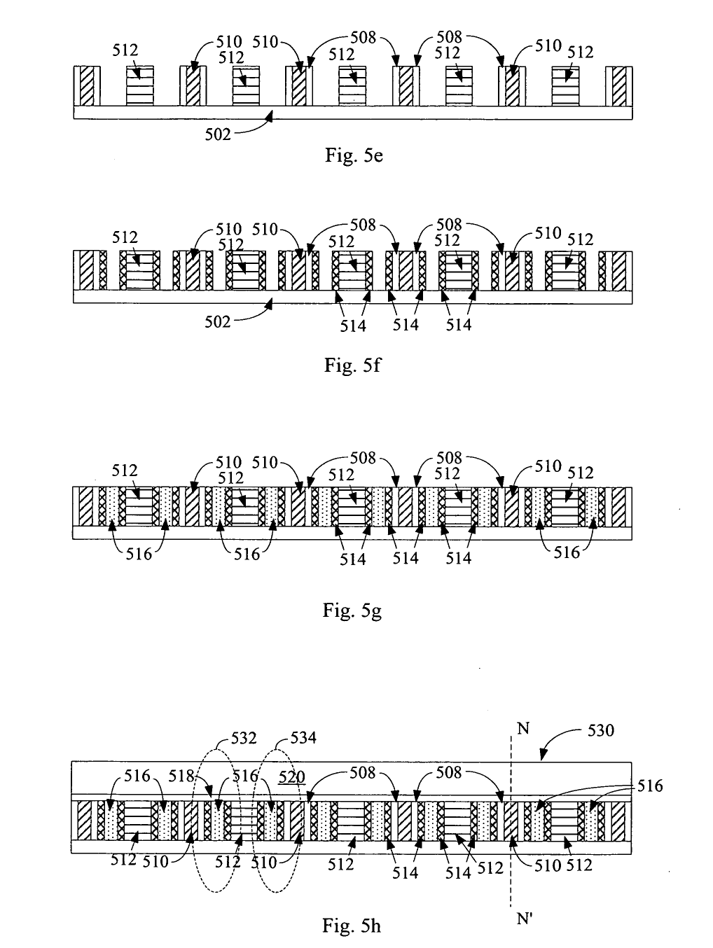

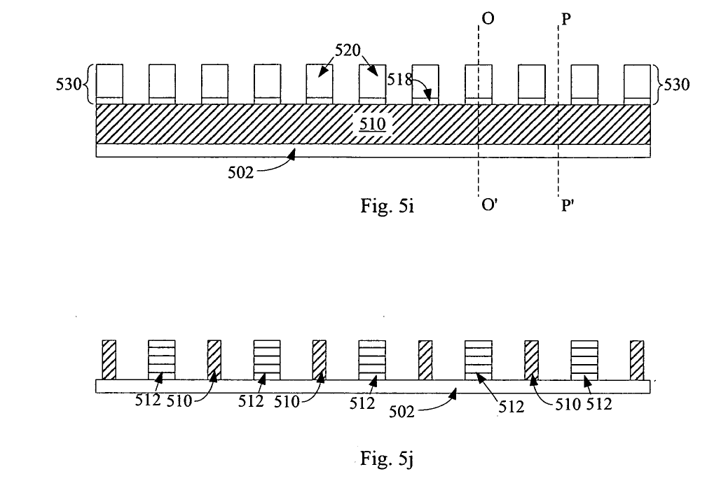

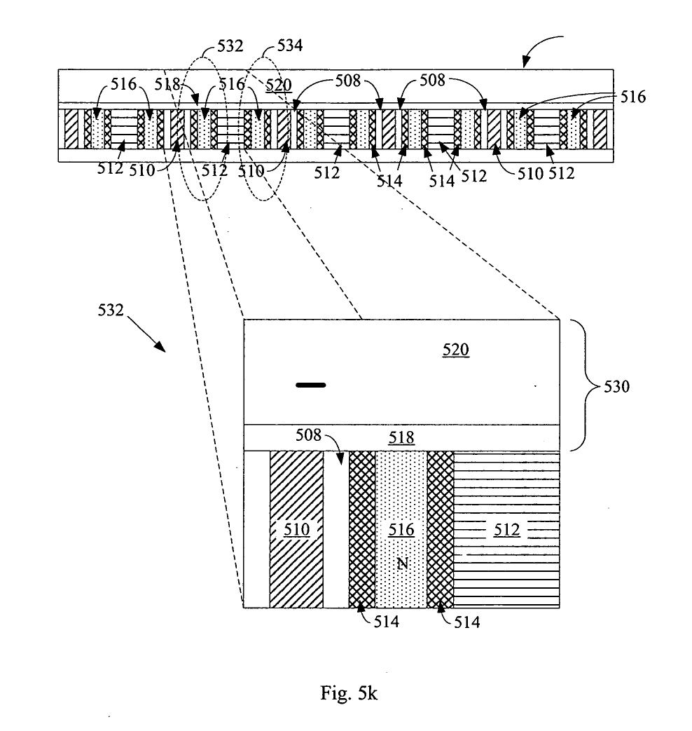

Turning to FIG. 5a, as in prior embodiments, fabrication begins over a substrate and insulating layer; for simplicity neither is shown. An etch stop layer 502 is deposited; this layer should be insulating and have good etch selectivity with silicon dioxide; silicon nitride or any other suitable dielectric material can be used.

A silicon dioxide layer 504 is deposited on silicon nitride layer 502 using any conventional method, and is preferably between about 170 and about 250 nm thick. (This thickness is selected to provide a final channel thickness between about 20 and about 90 nm, and allows for about 50 nm of thickness to be lost in each of three planarization steps to be described. The thickness of this initial layer 504 may be adjusted depending on the planarization methods used.) In the finished device, silicon dioxide layer 504 will be entirely removed; thus, if desired, some other material can be used instead. Silicon dioxide layer 504 is etched using conventional photolithography and etch techniques to form a series of slots 506, separated by silicon dioxide rails 504, shown in FIG. 5a in cross-section. The width of slots 506 is preferably about one feature size, or IF (feature size is the width of the smallest feature or gap formed by photolithography in a device), while the distance between slots 506 is preferably about three feature sizes, or 3F, where F is feature size.

Turning to FIG. 5b, spacers are formed of chalcogenide layer 508. To form chalcogenide spacers 508, a thin layer of chalcogenide material is conformally deposited over the etched silicon dioxide features 504 formed earlier, then an anisotropic etch, which etches faster vertically than laterally, is performed, removing chalcogenide from horizontal surfaces and leaving it only vertical surfaces.

Referring to FIG. 5c, a layer of ion reservoir material 510 is deposited over the structure, covering it and filling gaps between spacers 508. A planarization step, for example by CMP or etchback, removes the overfill of ion reservoir material 510, leaving it only between spacers 508.

As shown in FIG. 5d, in the next step another etch of silicon dioxide features 504 is performed, this time removing the center of each remaining silicon dioxide feature 504, forming gaps. These gaps are filled with a conductor 512, for example tungsten, and planarization, for example by CMP, leaves tungsten conductors 512, which are rail-shaped and extend out of the page. (If tungsten is used for conductors 512, a thin adhesion layer (not shown) may be deposited first to help the tungsten adhere.)

In FIG. 5e, a final etch of silicon dioxide 504 is performed to remove the remainder of it, leaving gaps between tungsten conductors 512 and spacers 508.

FIG. 5f illustrates the next step, in which spacers 514 are formed of a material that will form an ohmic contact with n-doped semiconductor material, such as TiN. TiN spacers 514 are formed using the same deposition and anisotropic etch described earlier.

In FIG. 5g, a doped semiconductor material 516, preferably silicon, germanium, or an alloy of silicon and/or germanium is deposited filling the remaining gaps, and a planarization step removes overfill. In the present embodiment, this layer is preferably moderately doped with an n-type dopant, for example to a concentration of between about 10¹⁷ and 10¹⁸ dopant atoms/cm³.

Turning to FIG. 5h, gate dielectric layer 518, which may be formed of any of the gate dielectric materials mentioned in prior embodiments, is deposited, followed by select line material 520, which may be any appropriate conductive material, for example tungsten, doped polysilicon, etc.

An etch step is performed to form select lines 530, which preferably extend perpendicular to tungsten rails 512 formed earlier. Select line material 520 and gate dielectric layer 518 are etched. The etch continues through doped semiconductor material 516, TiN spacers 514, and chalcogenide layer 508, isolating those materials between select lines 530. Selective etchants are chosen such that ion reservoir 510 and tungsten conductors 512 are not etched in this etch step. FIG. 5i shows the structure of FIG. 5h viewed at 90 degrees to the view of FIG. 5h along line N-N′. Conversely, FIG. 5h shows the structure of FIG. 5i viewed along line O-O′, along a select line 530, while the view of FIG. 5j is parallel to the view of FIG. 5h, viewed along line P-P′ of FIG. 5i, between select lines 530. Tungsten conductors 512 and conductive ion reservoirs 510 provide electrical connectivity to memory cells. Conductive ion reservoirs 510 can be considered to be data lines, while tungsten conductors 512 can be considered to be reference lines.

Memory cells are formed at locations 532 and 534 shown in FIG. 5h. FIG. 5k shows the view of FIG. 5h, including an expanded view of memory cell 532. Referring to the expanded view of memory cell 532 of FIG. 5k, this is a depletion mode device. It will be recalled that semiconductor layer 516 is moderately doped with an n-type dopant. When a small negative charge, for example about −0.5 volts, is applied to select line 530, electrons are repelled from semiconductor layer 516 (which serves as the channel layer), leaving it fully depleted and non-conductive. The switching device is in the “off” state. When a positive voltage, for example about 1 volt, is applied to select line 530, electrons return to channel layer 516. It will be recalled that layer 514 is formed of materials forming an ohmic contact with channel layer 516; thus a conduction path is formed and the switching device 532 is in the “on” state, though note that no inversion region has been formed in semiconductor layer 516. As in prior embodiments, ion reservoir 510, chalcogenide layer 508 and layer 514 form a switchable resistor memory element. By selecting appropriate voltages on tungsten conductor 512 and ion reservoir 510 (which is formed in a rail shape and serves as a conductor), this switchable resistor memory element can be switched between its low-resistance and high-resistance states.

In a related embodiment, this memory cell can instead be formed comprising an enhancement-mode MOSFET device. In this case channel layer 516 is formed of lightly doped p-type semiconductor material, while contacts 514 are formed of a material that forms a Schottky barrier with lightly doped p-type semiconductor material, such as ErSi_{1.7}. To form ErSi_{1.7}, in the step when layer 514 was deposited and TiN spacers formed (in FIG. 5f), instead a thin layer of silicon and a thin layer of erbium are deposited, then annealed to form ErSi_{1.7}. This can be done in various ways. For example, silicon spacers could be formed, a layer of erbium deposited over the structure and reacted with the spacers, then the unreacted erbium stripped; alternatively, the silicide reaction could precede the spacer etch. Other materials mentioned in other embodiments that will form a Schottky barrier with p-doped semiconductor material may be used as well.

A first memory level has been formed. As in prior embodiments, after formation of an interlevel dielectric, additional memory levels can be monolithically formed above the memory level shown in FIG. 5h. Any of the embodiments described herein can be formed as a monolithic three dimensional memory array.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

Embodiments of the present invention include a monolithic three dimensional memory array formed above a substrate comprising: a) a first memory level, the first memory level comprising a first plurality of nonvolatile memory cells, each first memory cell comprising: i) a switchable resistor memory element; and ii) a three-terminal switching device comprising a channel layer and a gate electrode, wherein the three-terminal switching device lacks a doped semiconductor source region, a doped semiconductor drain region, or both, and b) a second memory level monolithically formed above the first memory level.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A nonvolatile memory cell comprising:
a switchable resistor memory element; and
a thin film three-terminal switching device comprising a channel layer, the thin film three-terminal switching device in series with the switchable resistor memory element,
wherein the thin film three-terminal switching device does not include a doped semiconductor drain region, or
the thin film three-terminal switching device does not include a doped semiconductor source region, or
the thin film three-terminal switching device includes neither a doped semiconductor drain region nor a doped semiconductor source region.

2. The nonvolatile memory cell of claim 1 wherein, when the thin film three-terminal switching device is on, charge carriers travel through an inversion region formed in the channel layer between a first region in contact with the channel layer and a second region in contact with the channel layer.

3. The nonvolatile memory cell of claim 2 wherein the thin film three-terminal switching device is a MOSFET.

4. The nonvolatile memory cell of claim 3 wherein majority carriers in the inversion region are electrons.

5. The nonvolatile memory cell of claim 4 wherein the first region comprises a silicide in contact with the channel layer.

6. The nonvolatile memory cell of claim 5 wherein the silicide is ErSi_{1.7}, TaSiN, MoSiN, HfSiN, or TiSiN.

7. The nonvolatile memory cell of claim 4 wherein the first region comprises Al, Ti, Nb, Ag, Hf, Ta, Cu, Mn, W, or TiN in contact with the channel layer.

8. The nonvolatile memory cell of claim 3 wherein majority carriers in the inversion region are holes.

9. The nonvolatile memory cell of claim 8 wherein the first region comprises a silicide in contact with the channel layer.

10. The nonvolatile memory cell of claim 9 wherein the silicide is MoSi₂, WSi₂, or PtSi.

11. The nonvolatile memory cell of claim 9 wherein the first region comprises Au, Ni, or Pt in contact with the channel layer.

12. The nonvolatile memory cell of claim 1 wherein, when the thin film switching device is on, charge carriers travel through the channel layer between a first region in contact with the channel layer and a second region in contact with the channel layer, wherein both the first region and the second region consist essentially of a material that forms a substantially ohmic contact with the channel layer.

13. The nonvolatile memory cell of claim 12 wherein, when the thin film three-terminal switching device is off, the channel layer is in depletion mode.

14. The nonvolatile memory cell of claim 1 wherein the channel layer comprises silicon, germanium, or an alloy of silicon, germanium, or of silicon and germanium.

15. The nonvolatile memory cell of claim 14 wherein the channel layer comprises deposited semiconductor material.

16. The nonvolatile memory cell of claim 1 wherein the switchable resistor memory element comprises a layer of a binary metal oxide or nitride.

17. The nonvolatile memory cell of claim 1 wherein the switchable resistor memory element comprises a perovskite.

18. The nonvolatile memory cell of claim 1 wherein the switchable resistor memory element comprises a carbon polymer film.

19. The nonvolatile memory cell of claim 1 wherein the switchable resistor memory element comprises amorphous silicon doped with an element selected from the group consisting of V, Co, Ni, Pd, Fe, and Mn.

20. The nonvolatile memory cell of claim 1 wherein the switchable resistor memory element comprises a solid electrolyte material.

21. The nonvolatile memory cell of claim 20 wherein the solid electrolyte material comprises chalcogenide glass.

22. A monolithic three dimensional memory array formed above a substrate comprising:
a) a first memory level, the first memory level comprising a first plurality of nonvolatile memory cells, each first memory cell comprising:
i) a switchable resistor memory element; and
ii) a three-terminal switching device comprising a channel layer and a gate electrode, wherein the three-terminal switching device lacks a doped semiconductor source region, a doped semiconductor drain region, or both, and
b) a second memory level monolithically formed above the first memory level.

23. The monolithic three dimensional memory array of claim 22 wherein, when a threshold voltage is applied to the gate electrode, charge carriers travel through an inversion region in the channel layer between a first region in contact with the channel layer and a second region in contact with the channel layer, wherein the first region does not comprise semiconductor material, or the second region does not comprise semiconductor material, or neither the first nor the second region comprises semiconductor material.

24. The monolithic three dimensional memory array of claim 23 wherein the channel layer comprises silicon, germanium, or an alloy of silicon, germanium, or of silicon and germanium.

25. The monolithic three dimensional memory array of claim 24 wherein the first region or the second region comprises Al, Ti, Nb, Ag, Hf, Ta, Cu, Mn, W, or TiN, CoSi, PtSi, TaSiN, MoSiN, HfSiN, or TiSiN or ErSi_{1.7}.

26. The monolithic three dimensional memory array of claim 22 wherein the channel layer comprises deposited semiconductor material.

27. The monolithic three dimensional memory array of claim 22 wherein the switchable resistor memory element comprises a layer of a binary metal oxide or nitride.

28. The monolithic three dimensional memory array of claim 22 wherein the switchable resistor memory element comprises a perovskite.

29. The monolithic three dimensional memory array of claim 22 wherein the switchable resistor memory element comprises a carbon polymer film.

30. The monolithic three dimensional memory array of claim 22 wherein the switchable resistor memory element comprises amorphous silicon doped with an element selected from the group consisting of V, Co, Ni, Pd, Fe, and Mn.

31. The monolithic three dimensional memory array of claim 22 wherein the switchable resistor memory element comprises a solid electrolyte material.

32. The monolithic three dimensional memory array of claim 31 wherein the solid electrolyte material comprises chalcogenide glass.

33. A nonvolatile memory cell comprising:
a switchable resistor memory element; and
a thin film transistor comprising a channel layer and a gate electrode wherein, when a threshold voltage is applied to the gate electrode, an inversion region forms in the channel layer, and
current flows through the inversion region between a first region in contact with the channel layer and a second region in contact with the channel layer, wherein either the first region or the second region does not comprise semiconductor material.

34. The nonvolatile memory cell of claim 33 wherein the channel layer comprises silicon, germanium, or an alloy of silicon, germanium, or of silicon and germanium.

35. The nonvolatile memory cell of claim 33 wherein the first region or the second region comprises Al, Ti, Nb, Ag, Hf, Ta, Cu, Mn, W, or TiN, CoSi, PtSi, TaSiN, MoSiN, HfSiN, or TiSiN or ErSi_{1.7}.

36. The nonvolatile memory cell of claim 33 wherein the channel layer comprises deposited semiconductor material.

37. The nonvolatile memory cell of claim 33 wherein the switchable resistor memory element comprises a layer of a binary metal oxide or nitride.

38. The nonvolatile memory cell of claim 33 wherein the switchable resistor memory element comprises a perovskite.

39. The nonvolatile memory cell of claim 33 wherein the switchable resistor memory element comprises a carbon polymer film.

40. The nonvolatile memory cell of claim 33 wherein the switchable resistor memory element comprises amorphous silicon doped with an element selected from the group consisting of V, Co, Ni, Pd, Fe, and Mn.

41. The nonvolatile memory cell of claim 33 wherein the switchable resistor memory element comprises a solid electrolyte material.

42. The nonvolatile memory cell of claim 41 wherein the solid electrolyte material comprises chalcogenide glass.

43. A nonvolatile memory cell comprising:
a switchable resistor memory element; and
a three-terminal switching device having a channel layer, a source region, and a drain region, the three-terminal switching device and the switchable resistor memory element arranged in series,
wherein, when the transistor is on, charge carriers travel from the source region through the channel layer to the drain region,
wherein the nonvolatile memory cell comprises doped semiconductor material of only one conductivity type.

44. The nonvolatile memory cell of claim 43 wherein the thin film three-terminal switching device is an enhancement-mode MOSFET.

45. The nonvolatile memory cell of claim 44 wherein majority carriers in the inversion region are electrons.

46. The nonvolatile memory cell of claim 45 wherein the source region or the drain region comprises a silicide.

47. The nonvolatile memory cell of claim 46 wherein the silicide is ErSi_{1.7}, TaSiN, MoSiN, HfSiN, or TiSiN.

48. The nonvolatile memory cell of claim 45 wherein the first region comprises Al, Ti, Nb, Ag, Hf, Ta, Cu, Mn, W, or TiN, in contact with the channel layer.

49. The nonvolatile memory cell of claim 44 wherein majority carriers in the inversion region are holes.

50. The nonvolatile memory cell of claim 49 wherein the first region comprises a silicide.

51. The nonvolatile memory cell of claim 50 wherein the silicide is MoSi₂, WSi₂, or PtSi.

52. The nonvolatile memory cell of claim 49 wherein the first region comprises Au, Ni, or Pt in contact with the channel layer.

53. The nonvolatile memory cell of claim 43 wherein both the source region and the drain region consist essentially of a material in contact with the channel layer that forms a substantially ohmic contact with the channel layer.

54. The nonvolatile memory cell of claim 53 wherein, when the thin film three-terminal switching device is off, the channel layer is in depletion mode.

55. The nonvolatile memory cell of claim 43 wherein the channel layer comprises silicon, germanium, or an alloy of silicon, germanium, or of silicon and germanium.

56. The nonvolatile memory cell of claim 55 wherein the channel layer comprises deposited semiconductor material.

57. The nonvolatile memory cell of claim 43 wherein the switchable resistor memory element comprises a layer of a binary metal oxide or nitride.

58. The nonvolatile memory cell of claim 43 wherein the switchable resistor memory element comprises a perovskite.

59. The nonvolatile memory cell of claim 43 wherein the switchable resistor memory element comprises a carbon polymer film.

60. The nonvolatile memory cell of claim 43 wherein the switchable resistor memory element comprises amorphous silicon doped with an element selected from the group consisting of V, Co, Ni, Pd, Fe, and Mn.

61. The nonvolatile memory cell of claim 43 wherein the switchable resistor memory element comprises a solid electrolyte material.

62. The nonvolatile memory cell of claim 61 wherein the solid electrolyte material comprises chalcogenide glass.

63. A nonvolatile memory cell comprising:
a switchable resistor memory element; and
a thin film transistor comprising a channel layer, the thin film transistor and the switchable resistor memory element arranged in series,
wherein a source contact between the source region and the channel layer or a drain contact between the drain region and the channel layer is a Schottky contact.

64. The nonvolatile memory cell of claim 63 wherein, when the transistor is on, electrons flow between a source region in contact with the channel layer and a drain region in contact with the channel layer through an inversion region formed in the channel layer.

65. The nonvolatile memory cell of claim 64 wherein the thin film transistor is an enhancement-mode MOSFET.

66. The nonvolatile memory cell of claim 65 wherein majority carriers in the inversion region are electrons.

67. The nonvolatile memory cell of claim 66 wherein the source region or the drain region comprises a silicide.

68. The nonvolatile memory cell of claim 67 wherein the silicide is ErSi_{1.7},TaSiN, MoSiN, HfSiN, or TiSiN.

69. The nonvolatile memory cell of claim 67 wherein the first region comprises Al, Ti, Nb, Ag, Hf, Ta, Cu, Mn, W, or TiN, in contact with the channel layer.

70. The nonvolatile memory cell of claim 65 wherein majority carriers in the inversion region are holes.

71. The nonvolatile memory cell of claim 70 wherein the first region comprises a silicide.

72. The nonvolatile memory cell of claim 71 wherein the silicide is MoSi₂, WSi₂, or PtSi.

73. The nonvolatile memory cell of claim 70 wherein the first region comprises Au, Ni, or Pt in contact with the channel layer.

74. The nonvolatile memory cell of claim 63 wherein, when the transistor is on, electrons flow between a source region in contact with the channel layer and a drain region in contact with the channel layer through a majority carrier region in the channel layer.
